(19) United States
(12) Patent Application Publication
(10) Pub. No.: US 2025/0081407 A1
(43) Pub. Date: Mar. 6, 2025

(54) COOLING SYSTEMS AND METHODS FOR SERVER RACKS IN DATA CENTERS

(71) Applicant: Arnold Castillo Magcale, Danville, CA (US)

(72) Inventor: Arnold Castillo Magcale, Danville, CA (US)

(21) Appl. No.: 18/240,508

(22) Filed: Aug. 31, 2023

(51) Int. Cl. H05K 7/20

(52) U.S. Cl. CPC H05K 7/20836; H05K 7/20745; H05K 7/20781

(57) ABSTRACT

Embodiments disclosed include systems and methods for rack mounted cooling of data centers comprising a rear door heat exchanger configured to mount to a rear end of a housing within which an electronic system is contained, the rear door heat exchanger comprising, a coolant distribution unit operatively coupled to a coolant-carrying channel comprising a coolant inlet plenum and a coolant outlet plenum extending there through the housing in a closed loop configuration. Embodiments include a single or plurality of variable frequency drive (VFD) fans configured to circulate heated air through the coolant carrying channel, and a return path or closed loop configured to re-circulate air cooled via the coolant carrying channel through the electronic system. In preferred embodiments, the coolant carrying channel comprises a plurality of configurable internal valves operable to regulate the flow of the liquid according to a pre-defined temperature parameter. Additionally and preferably, the plurality of configurable internal valves are autonomously controlled by a data center infrastructure management (DCIM) software.

### BACKGROUND

Background description includes information that may be useful in understanding the present invention. It is not an admission that any of the information provided herein is prior art or relevant to the presently claimed invention, or that any publication specifically or implicitly referenced is prior art.

The term “data center” (also sometime referred to as a “server farm”) loosely refers to a physical location housing one or more “servers.” In some instances, a data center can simply comprise an unobtrusive corner in a small office. In other instances, a data center can comprise several large, warehouse-sized buildings enclosing tens of thousands of square feet and housing thousands of servers. The term “server” generally refers to a computing device connected to a computing network and running software configured to receive requests (e.g., a request to access or to store a file, a request to provide computing resources, a request to connect to another client) from client computing devices, includes PDAs and cellular phones, also connected to the computing network. Such servers may also include specialized computing devices called network routers, data acquisition equipment, movable disc drive arrays, and other devices commonly associated with data centers.

Typical commercially-available servers have been designed for air cooling. Such servers usually comprise one or more printed circuit boards having a plurality of electrically coupled devices mounted thereto. These printed circuit boards are commonly housed in an enclosure having vents that allow external air to flow into the enclosure, as well as out of the enclosure after being routed through the enclosure for cooling purposes. In many instances, one or more fans are located within the enclosure to facilitate this airflow.

“Racks” have been used to organize several servers. For example, several servers can be mounted within a rack, and the rack can be placed within a data center. Any of various computing devices, such as, for example, network routers, hard-drive arrays, data acquisition equipment and power supplies, are commonly mounted within a rack.

Data centers housing such servers and racks of servers typically distribute air among the servers using a centralized fan (or blower). As more fully described below, air within the data center usually passes through a heat exchanger for cooling the air (e.g., an evaporator of a vapor-compression cycle refrigeration cooling system (or “vapor-cycle” refrigeration), or a chilled water coil) before entering a server. In some data centers, the heat exchanger has been mounted to the rack to provide “rack-level” cooling of air before the air enters a server. In other data centers, the air is cooled before entering the data center.

In general, electronic components of higher performing servers dissipate correspondingly more power. However, power dissipation for each of the various hardware components (e.g., chips, hard drives, cards) within a server can be constrained by the power being dissipated by adjacent heat generating components, the airflow speed and airflow path through the server and the packaging of each respective component, as well as a maximum allowable operating temperature of the respective component and a temperature of the cooling air entering the server as from a data center housing the server. The temperature of an air stream entering the server from the data center, in turn, can be influenced by the power dissipation and proximity of adjacent servers, the airflow speed and the airflow path through a region surrounding the server, as well as the temperature of the air entering the data center (or, conversely, the rate at which heat is being extracted from the air within the data center).

In general, a lower air temperature in a data center allows each server component to dissipate a higher power, and thus allows each server to dissipate more power and operate at a level of hardware performance. Consequently, data centers have traditionally used sophisticated air conditioning systems (e.g., chillers, vapor-cycle refrigeration) to cool the air (e.g., to about 65° F.) within the data center for achieving a desired performance level. By some estimates, as much as one watt can be consumed to remove one watt of heat dissipated by an electronic component. Consequently, as energy costs and power dissipation continue to increase, the total cost of cooling a data center has also increased.

In general, spacing heat-dissipating components from each other (e.g., reducing heat density) makes cooling such components less difficult (and less costly when considering, for example, the cost of cooling an individual component in a given environment) than placing the same components placed in close relation to each other (e.g., increasing heat density). Consequently, data centers have also compensated for increased power dissipation (corresponding to increased server performance) by increasing the spacing between adjacent servers.

In addition, large-scale data centers have provided several cooling stages for cooling beat dissipating components. For example, a stream of coolant, e.g., water, can pass over an evaporator of a vapor-compression refrigeration cycle cooling system and be cooled to, for example, about 44° F. before being distributed through a data center for cooling air within the data center.

The power consumed by a chiller can be estimated using information from standards (e.g., ARI 550/590-98). For example, ARI550/590-98 specifies that a new centrifugal compressor, an efficient and common compressor used in high-capacity chillers, has a seasonal average Coefficient-of-Performance (“COP”) from 5.00 to 6.10, depending on the cooling capacity of the chiller. This COP does not include power consumed by an evaporative cooling tower, which can be used for cooling a condenser in the refrigeration cycle cooling system and generally has a COP of 70, or better. The combined COP for a typical system is estimated to be about 4.7.

According to some estimates, some state-of-the-art data centers are capable of cooling only about 150 Watts-per-square-foot, as opposed to cooling the more than about 1,200 Watts-per-square-foot that could result from arranging servers to more fully utilize available volume (e.g., closely spacing servers and racks to more fully utilize floor-to-ceiling height and floor space) within existing data centers. Such a low cooling capacity can significantly add to the cost of building a data center, since data centers can cost as much as about $250 per-square-foot to construct.

As the air-cooling example implies, commercially available methods of air cooling have not kept pace with increasing server density and data-center performance needs, and thus the corresponding growth in heat density. As a consequence, adding new servers to existing data centers has become difficult and complex given the effort expended to facilitate additional power dissipation, such as by increasing an existing data center's air conditioning capacity.

Various alternative approaches for cooling data centers and their servers, e.g., using liquid cooling systems, have met with limited success. For example, attempts to displace heat from a microprocessor (or other heat-generating semiconductor-fabricated electronic device component, collectively referred to herein as a “chip”) for remotely cooling the chip have been expensive and cumbersome. In these systems, a heat exchanger or other cooling device, has been placed in physical contact (or close physical relation using a thermal-interface material) with the package containing the chip. These liquid-cooled heat exchangers have typically defined internal flow channels for circulating a liquid internally of a heat exchanger body. However, component locations within servers can vary from server to server. Accordingly, these liquid-cooling systems have been designed for particular component layouts and have been unable to achieve large-enough economies of scale to become commercially viable. Further, there always remains the possibility of leakages and damage to an entire system due to even a minor leak. Yet additionally, scaling up cooling to match increasing capacity remains a challenge.

Control systems have been used to increase cooling rates for a plurality of computers in response to increased computational demand. Even so, such control systems have controlled cooling systems that dissipate heat into the data center building interior air (which in turns needs to be cooled by air conditioning), or directly use refrigeration as a primary mode of heat dissipation. Refrigeration as a primary mode of cooling, directly or indirectly, requires significant amounts of energy.

Two-phase cooling systems have been attempted, but due to technical complexity, they have not resulted in cost-effective products or sufficiently low operating costs to justify investing in two-phase-cooling capital. Still other single- and two-phase cooling systems bring the coolant medium to an exterior of the computer, but reject heat to a cooling medium (e.g., air) external to the computer and within the data center (e.g., within a server room). Accordingly, each method of server or computer cooling currently employed or previously attempted have been prohibitively expensive and/or insufficient to meet increasing cooling demands of computing devices.

Indirectly, many researchers have tried to reduce the power of individual components such as the power supply and CPU. Although chips capable of delivering desirable performance levels while operating at a lower relative power have been offered by chip manufacturers, such chips have, to date, been expensive. Consequently, cooling approaches to date have resulted in one or more of a high level of electricity consumption, a large capital investment and an increase in hardware expense.

### SUMMARY

One general aspect includes a rear door heat exchanger configured to mount to a rear end of a housing within which an electronic system is contained. The rear door heat exchanger also includes a coolant distribution unit operatively coupled to a coolant-carrying channel which comprises a coolant inlet plenum and a coolant outlet plenum extending there through the housing in a closed loop configuration. Preferably, a single or plurality of variable frequency drive (VFD) fans are configured to circulate heated air through the coolant carrying channel, and a return path or closed loop is configured to re-circulate air cooled via the coolant carrying channel through the electronic system. According to an embodiment, the coolant carrying channel may include a plurality of configurable internal valves operable to regulate the flow of the liquid according to a pre-defined temperature parameter, and where the plurality of configurable internal valves are autonomously controlled by a data center infrastructure management (DCIM) software. Other embodiments of this aspect include corresponding computer systems, apparatus, and computer programs recorded on one or more computer storage devices, each configured to perform the actions of the methods.

Implementations may include one or more of the following features. According to an embodiment, the coolant distribution unit is further coupled to a heat dissipator. Additionally, the rear door heat exchanger may include a thermal monitoring sensor configured to measure the exit temperature and the inlet temperature of the circulating air through the electronic system. The dynamic control of the temperature of the electronic system further may include directing the air to specific targeted portions of the electronic system by the single or plurality of vents. The single or plurality of variable frequency drive (VFD) fans are further configured to, dynamically control the flow of air based on a thermal measurement. Implementations of the described techniques may include hardware, a method or process, or computer software on a computer-accessible medium.

An embodiment includes a cooling system comprising an air coolant loop in thermal communication with a non-air coolant loop and a coolant distribution unit for heat transfer between the air coolant loop and the non-air coolant loop. According to one embodiment, air coolant loop is utilized in cooling ambient air circulated across heat transfer surfaces via variable frequency drive (VFD) fans configured to vary the flow across the said surfaces based on sensor detected temperatures to accurately maintain the temperature of the equipment within an acceptable range. Preferably, heat is transferred from the ambient air to the air loop, and further, heat is transferred from the air loop to the non-air loop via coolant distribution unit. A heat dissipator thermally coupled to coolant distribution unit may serve to dissipate the heat to the outside environment. According to a preferred embodiment, non-air loop deploys a plant based, liquid coolant that is environmentally friendly. Alternatives like freon based coolants are possible, as would be apparent to a person having ordinary skill in the art. According to an alternative embodiment, the system may be implemented as a number of modular units wherein each unit has a cooling capacity sufficient for a subset of a data center environment. Further, and preferably, modularity is designed to be scalable in a plug and play fashion, so that as the number of racks in the data center increase or/and decrease, the corresponding cooling units can be plugged or unplugged to and from existing cooling systems without disrupting an entire data center.

### BRIEF DESCRIPTION OF THE DRAWINGS

FIG. 1 is a front view of a rear door heat exchanger (RDHX) according to an embodiment.

FIG. 2 illustrates cold air-flow through heat generating equipment and a dedicated return path for the warmer-air back to the rear door heat exchanger (RDHX) to be cooled and re-circulated.

FIG. 3 illustrates a data center rack comprising a rack mounted rear door heat exchanger (RDHX) and boxed into an air-tight or semi-air-tight compartment.

FIG. 4 illustrates an alternate embodiment of the cooling system.

### DETAILED DESCRIPTION

Specific embodiments of the invention will now be described in detail with reference to the accompanying figures. Like elements in the various figures are denoted by like reference numerals for consistency.

In the following detailed description of embodiments of the invention, numerous specific details are set forth in order to provide a more thorough understanding of the invention. In other instances, well-known features have not been described in detail to avoid obscuring the invention.

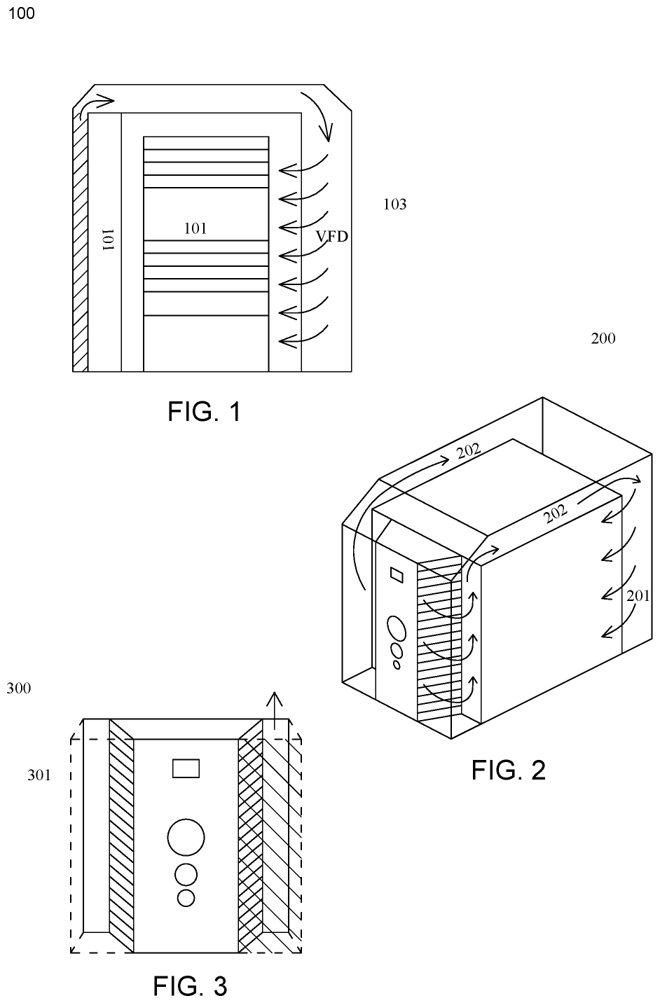

FIG. 1 is a front view of a rear door heat exchanger (RDHX) according to an embodiment. Illustrated in FIG. 1 100 is the rear door heat exchanger (RDHX) 101 mounted to the back of a data center rack and a single or plurality of variable frequency drive (VFD) fans configured to pull hot air from the front of the data center rack and pass the hot air through the rear door heat exchanger (RDHX). According to an embodiment the RDHX is a liquid cooled heat exchanger comprising a plant based environmentally friendly refrigerant in a coolant distribution unit (CDU). Other refrigerants like freon may also be used, as would be apparent to a person having ordinary skill in the art. A second plurality of variable frequency drive (VFD) fans 104 are configured to push air cooled by the RDHX to the front of the rack through heat generating components wherein the cooled air carries the heat away from the heat generating components as it is pulled by the single or plurality of VFD's 103.

Embodiments disclosed include a rear door heat exchanger configured to mount to a rear end of a housing within which an electronic system is contained, the rear door heat exchanger comprising a coolant distribution unit operatively coupled to a coolant-carrying channel comprising a coolant inlet plenum and a coolant outlet plenum extending there through the housing in a closed loop configuration. According to an embodiment, a single or plurality of variable frequency drive (VFD) fans are configured to circulate heated air through the coolant carrying channel. A preferred embodiment includes a return path or closed loop configured to re-circulate air cooled via the coolant carrying channel through the electronic system.

FIG. 2 illustrates an aspect view of the system, particularly depicting air-flow according to an embodiment. FIG. 2 200 illustrates cold air-flow 201 through heat generating equipment and a dedicated return path 202 for the warmer-air back to the rear door heat exchanger (RDHX) to be cooled and re-circulated. Preferably, the dedicated return path 202 is separate or/and insulated from the heat generating components. According to an alternate embodiment, the coolant carrying channel comprises a plurality of configurable internal valves operable to regulate the flow of the liquid according to a pre-defined temperature parameter; In one embodiment, the plurality of configurable internal valves are autonomously controlled by a data center infrastructure management (DCIM) software.

According to an embodiment of the rear door heat exchanger the coolant distribution unit is further coupled to a heat dissipator. Preferably, the rear door heat exchanger further comprising a thermal monitoring sensor configured to measure the exit temperature and the inlet temperature of the circulating air through the electronic system. According to an alternate embodiment, the rear door heat exchanger comprises a single or plurality of vents configured to dynamically control the temperature of the electronic system in conjunction with the coolant flow and the air flow; and wherein the dynamic control of the temperature of the electronic system further comprises directing the air to specific targeted portions of the electronic system by the single or plurality of vents. According to an embodiment of the rear door heat exchanger the single or plurality of variable frequency drive (VFD) fans are further configured to, dynamically control the flow of air based on a thermal measurement.

FIG. 3 300 illustrates a data center rack comprising a rack mounted rear door heat exchanger (RDHX) and boxed into an air-tight or semi-air-tight compartment. According to an embodiment the compartment 310 further comprises a single or plurality of sensor controlled vents (not shown) configured to release warm air beyond a threshold temperature and further configured to allow ambient air to be circulated through the heat generating components of the data center rack, and to be re-circulated through the rear door heat exchanger (RDHX).

Embodiments disclosed include, in a rear door heat exchanger configured to mount to a rear end of a housing within which an electronic system is contained, a method of cooling the electronic system comprising circulating a coolant via a coolant distribution unit operatively coupled to a coolant-carrying channel comprising a coolant inlet plenum and a coolant outlet plenum extending there through the housing in a closed loop configuration. A preferred embodiment of the method includes circulating heated air through the coolant carrying channel via a single or plurality of variable frequency drive (VFD) fans configured to circulate the heated air through the coolant carrying channel. According to an embodiment, the method includes re-circulating air cooled via the coolant carrying channel through the electronic system in a return path or closed loop. Alternatively, the method includes regulating a coolant flow through the coolant carrying channel via a plurality of configurable internal valves comprised in the coolant carrying channel according to a pre-defined temperature parameter, and autonomously controlling the plurality of configurable internal valves by a data center infrastructure management (DCIM) software.

According to an embodiment, heat captured by the coolant carrying channel is dissipated by a heat dissipator operatively coupled to the coolant distribution unit. Additionally, the method further comprises measuring the exit temperature and the inlet temperature of the circulating air via a thermal monitoring sensor.

An embodiment comprises dynamically controlling the temperature of the electronic system in conjunction with the coolant flow and the air flow via a single or plurality of vents comprised in the return path or closed loop, and according to a preferred embodiment, dynamically controlling the temperature of the electronic system further comprises directing the air to specific targeted portions of the electronic system by the single or plurality of vents. An embodiment further comprises dynamically controlling the flow of air based on a thermal measurement by the single or plurality of variable frequency drive (VFD) fans.

According to an alternate embodiment, the heat exchanger comprises a low pressure, high velocity closed loop air cooling circuit wherein the closed loop air cooling circuit is operatively coupled to a liquid coolant distribution unit distant from the data center rack or racks. Preferably, sensor controlled variable frequency drive fans are configured to blow ambient air through the high velocity closed loop air cooling circuit over the heat generating components of the data center and re-circulate the heated air through the high velocity closed loop air cooling circuit.

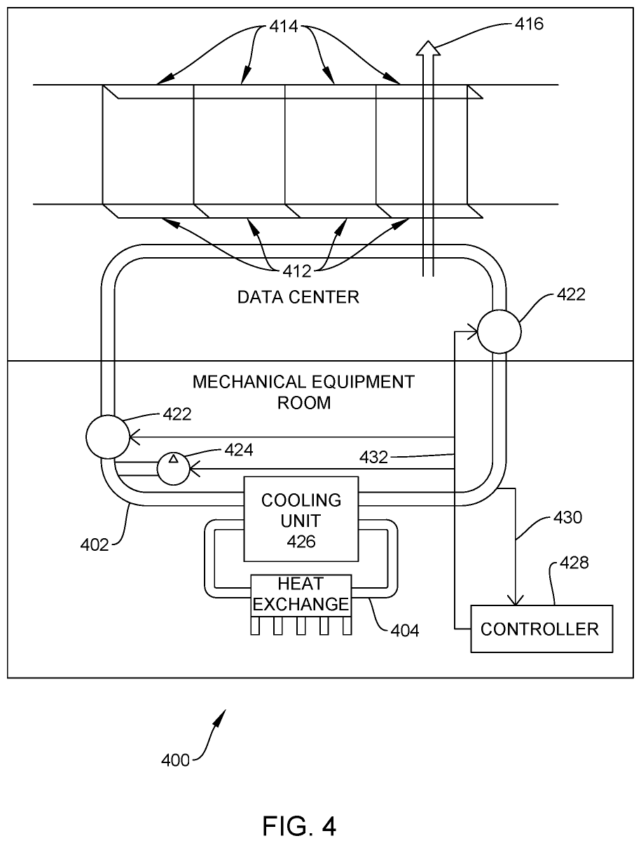

FIG. 4 illustrates an alternate embodiment of the cooling system. The system 400 generally includes an air coolant loop 402, a non-air coolant loop 404 and a coolant distribution unit 426 for heat transfer between the air coolant loop and the non-air coolant loop. Air coolant loop 402 is utilized in cooling ambient air circulated across heat transfer surfaces via variable frequency drive (VFD) fans configured to vary the flow across the said surfaces based on sensor detected temperatures to accurately maintain the temperature of the equipment within an acceptable range. In this process, heat is transferred from the ambient air to the air loop 402. Further, heat is transferred from the air loop 402 to the non-air loop 404 via coolant distribution unit 426. A heat dissipator thermally coupled to coolant distribution unit 426 may serve to dissipate the heat to the outside environment. According to a preferred embodiment, non-air loop 404 deploys a plant based, liquid coolant that is environmentally friendly. Alternatives like freon based coolants are possible, as would be apparent to a person having ordinary skill in the art. According to an alternative embodiment, the system may be implemented as a number of modular units wherein each unit has a cooling capacity sufficient for a subset of a data center environment. Further, and preferably, modularity is designed to be scalable in a plug and play fashion, so that as the number of racks in the data center increase or/and decrease, the corresponding cooling units can be plugged or de-plugged to and from existing cooling systems without disrupting an entire data center.

According to an embodiment, the air in air loop 402 is maintained at a low pressure and transmitted at a high speed. To achieve the desired heat transfer effect, a greater volume of the low pressure, low density coolant needs to be passed through the heat transfer surface. According to a preferred embodiment, maintaining the pressure below 5 atmospheres (or 80 psi) enables the modular functionality of the invention and associated tubing connections and disconnections. According to an embodiment, the air in air loop 402 is maintained at 3 atmospheres (or 48 psi). As discussed above, the use of such a low pressure coolant generally means that higher coolant speeds will be required to achieve the desired heat transfer capacity. Accordingly, it is desirable to drive the air within loop 402 at a speed in excess of 50 mph for typical data center applications. In the illustrated embodiment, the air in loop 402 is driven at a speed of between about 75-90 mph.

To achieve the desired air circulation and other air properties, the illustrated loop 402 includes one or more circulation pumps 422 and one or more air compressor and dryer units 424. The pumps 422 drive the air in the loop 402 at the desired speeds as discussed above. Any appropriate pumps may be used in this regard.

The air compressor and dryer unit 424 dehumidifies the air injected into the system and pressurizes the air so that the desired air pressure level in the closed loop is maintained. In order to achieve the desired heat transfer effect, the cooler unit 426 maintains the air in the loop 402 at a low temperature. The specific temperature depends on a number of factors including the needs of the particular data center application, ambient temperature and humidity levels and the insulating properties of the conduits from which the loop 402 is constructed. In particular, it may be desired to control operation of the system 400 such that the external surface temperature of the loop 402 is maintained within a controlled temperature band so as to avoid excess condensation that may be hazardous in a data center environment. For example, it may be desired to maintain the temperature of the external surface of the loop 402 within a temperature band of about 40° F.-60° F. for example, between about 50° F.-55° F. However, the air within the loop 402 may be maintained at a considerably colder temperature when an insulating conduit structure, as will be described below, is employed. In this regard, the air within the loop 402 may be maintained at temperatures below freezing, for example, about −40° F. The air compressor and dryer unit 424 thus reduces the humidity level of air injected into the loop 402, and reduces the humidity level of air introduced into the loop 402 due to reconfiguration of the system, so that water does not freeze in the loop 402.

As shown, the non-air loop 404 and associated components are preferably disposed outside of the data center 418, for example, in a mechanical equipment room 420. In this manner, air is the only coolant introduced into the data center 418 and any leakage of non-air coolants will be restricted to areas outside of the data center 418. The air in the loop 402 is used to cool equipment disposed in the racks 410. Generally, this may be accomplished by using the loop 402 to cool ambient air, which can then be blown across heat transfer surfaces of the equipment. As the racks 410 are typically organized side-by-side in rows, this can generally be most effectively accomplished by blowing the ambient air in a front-to-back or back-to-front direction across the equipment. The illustrated system blows air from front-to-back as generally indicated by the arrow 416. This can be done by disposing one or more fans either in front of or behind a rack 410 and, for many applications, fans associated with a chiller on the front side of the racks 410, to cool ambient air before it is delivered to the equipment, will be sufficient. In the illustrated embodiment, the front doors of the racks 410 are replaced with air-to-air chillers with integrated fans 412, and the rear panels of the racks 410 are replaced with optional air flow boost doors with integrated fans 414.

An alternate embodiment includes creating a passage for non-pressurized air to flow in and re-circulate in the data center racks at an acceptable/optimum velocity and to carry the heat from heat generating components in the data center rack to the non-air based cooling unit before being chilled, dried and recirculated.

Embodiments disclosed include systems and methods that provide an effective, efficient and low-cost cooling alternative for cooling electronic components, such as, for example, rack-mounted servers. Additionally, embodiments disclosed include systems and methods that enable increased efficiency of air cooled rack mounted servers. Systems and methods disclosed the dangers and complications of direct heat transfer liquid based cooling systems, and additionally, enable modularity and thus scalable cooling systems to match increasing capacity of rack mounted server systems in data centers and support scalability of such rack mounted server systems in data centers. Yet additionally, embodiments disclosed enable minimizing use of artificial or/and chemical refrigerants due to the low pressure high velocity air circulation, and in some instances embodiments enable replacing such refrigerants by plant based refrigerants in cooling systems.

Since various possible embodiments might be made of the above invention, and since various changes might be made in the embodiments above set forth, it is to be understood that all matter herein described or shown in the accompanying drawings is to be interpreted as illustrative and not to be considered in a limiting sense. Thus, it will be understood by those skilled in the art of cooling systems and methods, and more particularly cooling systems and methods for data centers, that although the preferred and alternate embodiments have been shown and described in accordance with the Patent Statutes, the invention is not limited thereto or thereby.

The figures illustrate the architecture, functionality, and operation of possible implementations of systems, methods and computer program products according to various embodiments of the present invention. It should also be noted that, in some alternative implementations, the functions noted/illustrated may occur out of the order noted in the figures. For example, two blocks shown in succession may, in fact, be executed concurrently, or the blocks may sometimes be executed in the reverse order, depending upon the functionality involved.

The terminology used herein is for the purpose of describing embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

In general, the routines executed to implement the embodiments of the invention, may be part of an operating system or a specific application, component, program, module, object, or sequence of instructions. The computer program of the present invention typically is comprised of a multitude of instructions that will be translated by the native computer into a machine-accessible format and hence executable instructions. Also, programs are comprised of variables and data structures that either reside locally to the program or are found in memory or on storage devices. In addition, various programs described hereinafter may be identified based upon the application for which they are implemented in a specific embodiment of the invention. However, it should be appreciated that any program nomenclature that follows is used merely for convenience, and thus the invention should not be limited to use solely in any specific application identified and/or implied by such nomenclature.

The present invention and some of its advantages have been described in detail for some embodiments. It should be understood that although the system and process are described with reference to cooling systems and methods for data centers, the system and method is highly reconfigurable, and may be used in other systems as well. Portions of the embodiment may be used to support cooling systems and methods for other types of data communication systems, residential buildings, offices, factories or/and facilities. Modifications of the embodiments may be used to capture emitted heat from heat sources and convert the captured heat to electricity to serve as an auxiliary or primary power source. It should also be understood that various changes, substitutions and alterations can be made herein without departing from the spirit and scope of the invention as defined by the appended claims. An embodiment of the invention may achieve multiple objectives, but not every embodiment falling within the scope of the attached claims will achieve every objective. Moreover, the scope of the present application is not intended to be limited to the embodiments of the process, machine, manufacture, composition of matter, means, methods and steps described in the specification. A person having ordinary skill in the art will readily appreciate from the disclosure of the present invention that processes, machines, manufacture, compositions of matter, means, methods, or steps, presently existing or later to be developed are equivalent to, and fall within the scope of, what is claimed. Accordingly, the appended claims are intended to include within their scope such processes, machines, manufacture, compositions of matter, means, methods, or steps.

We claim:

1. A rear door heat exchanger configured to mount to a rear end of a housing within which an electronic system is contained, the rear door heat exchanger comprising:
a coolant distribution unit operatively coupled to a coolant-carrying channel comprising a coolant inlet plenum and a coolant outlet plenum extending there through the housing in a closed loop configuration;
a single or plurality of variable frequency drive (VFD) fans configured to circulate heated air through the coolant carrying channel;
a return path or closed loop configured to re-circulate air cooled via the coolant carrying channel through the electronic system;
wherein the coolant carrying channel comprises a plurality of configurable internal valves operable to regulate the flow of the liquid according to a pre-defined temperature parameter; and
wherein the plurality of configurable internal valves are autonomously controlled by a data center infrastructure management (DCIM) software.

2. The rear door heat exchanger of claim 1 wherein the coolant distribution unit is further coupled to a heat dissipator.

3. The rear door heat exchanger of claim 1 further comprising a thermal monitoring sensor configured to measure the exit temperature and the inlet temperature of the circulating air through the electronic system.

4. The rear door heat exchanger of claim 1 further comprising a single or plurality of vents configured to dynamically control the temperature of the electronic system in conjunction with the coolant flow and the air flow; and
wherein the dynamic control of the temperature of the electronic system further comprises directing the air to specific targeted portions of the electronic system by the single or plurality of vents.

5. The rear door heat exchanger of claim 1 wherein the single or plurality of variable frequency drive (VFD) fans are further configured to, dynamically control the flow of air based on a thermal measurement.

6. In a rear door heat exchanger configured to mount to a rear end of a housing within which an electronic system is contained, a method of cooling the electronic system comprising:
circulating a coolant via a coolant distribution unit operatively coupled to a coolant-carrying channel comprising a coolant inlet plenum and a coolant outlet plenum extending there through the housing in a closed loop configuration;
circulating heated air through the coolant carrying channel via a single or plurality of variable frequency drive (VFD) fans configured to circulate the heated air through the coolant carrying channel;
re-circulating air cooled via the coolant carrying channel through the electronic system in a return path or closed loop;
regulating a coolant flow through the coolant carrying channel via a plurality of configurable internal valves comprised in the coolant carrying channel according to a pre-defined temperature parameter; and
autonomously controlling the plurality of configurable internal valves by a data center infrastructure management (DCIM) software.

7. The method of claim 6 further comprising dissipating heat captured by the coolant carrying channel by a heat dissipator operatively coupled to the coolant distribution unit.

8. The method of claim 6 further comprising measuring the exit temperature and the inlet temperature of the circulating air via a thermal monitoring sensor.

9. The method of claim 6 further comprising dynamically controlling the temperature of the electronic system in conjunction with the coolant flow and the air flow via a single or plurality of vents comprised in the return path or closed loop; and
wherein dynamically controlling the temperature of the electronic system further comprises directing the air to specific targeted portions of the electronic system by the single or plurality of vents.

10. The method of claim 6 further comprising dynamically controlling the flow of air based on a thermal measurement by the single or plurality of variable frequency drive (VFD) fans.

11. A cooling system including a heat exchanger apparatus comprising:
an air coolant loop in thermal communication with a non-air coolant loop;
a coolant distribution unit for heat transfer between the air coolant loop and the non-air coolant loop;
a single or plurality of variable frequency drive (VFD) fans configured to vary the flow of air across a single or plurality of heat transfer surfaces based on sensor detected temperatures to accurately maintain the temperature of equipment within an acceptable range;
wherein heat is transferred from the ambient air to the air loop, and further from the air loop to the non-air loop via coolant distribution unit; and
a heat dissipator thermally coupled to said coolant distribution unit.

12. The cooling system of claim 11 wherein the air coolant loop is a low pressure high velocity air coolant loop.

13. The cooling system of claim 11 wherein the coolant distribution unit circulates a plant based liquid coolant.
